(19) United States
(12) Patent Application Publication
(10) Pub. No.: US 2013/0189835 A1
(43) Pub. Date: Jul. 25, 2013

(54) METHOD FOR CLEANING A SEMICONDUCTOR DEVICE

(71) Applicant: Renesas Electronics Corporation, Kawasaki-Shi (JP)

(72) Inventors: Hirokazu KURISU, Kanagawa (JP); Yutaka TAKESHIMA, Kanagawa (JP); Itaru KANNO, Kanagawa (JP); Masahiko HIGASHI, Kanagawa (JP); Yusaku HIROTA, Kanagawa (JP)

(73) Assignee: RENESAS ELECTRONICS CORPORATION, Kawasaki-Shi (JP)

(21) Appl. No.: 13/706,056

(22) Filed: Dec. 5, 2012

Related U.S. Application Data
(62) Division of application No. 12/819,675, filed on Jun. 21, 2010, now abandoned.

(30) Foreign Application Priority Data
Jun. 25, 2009 (JP) 2009-151288

(51) Int. Cl. H01L 21/02

(52) U.S. Cl. CPC H01L 21/02063
USPC 438/592

(57) ABSTRACT

A method of cleaning a semiconductor device that both inhibits dissolution of gate metal material and acquires favorable contact resistance. The gate of the device is multilayered, with stacked layers of metal and silicide beneath an insulation layer and atop a silicon substrate. A shared contact hole formed in the insulation layer exposes the silicide layer and multilayer gate from the insulation layer. The shared contact hole is subjected to sulfuric acid, aqueous hydrogen peroxide and APM cleaning processes, separately, to remove an altered layer that tends to form in the shared contact hole.

### CROSS-REFERENCE TO RELATED APPLICATIONS

The disclosure of Japanese Patent Application No. 2009-151288 filed on Jun. 25, 2009 including the specification, drawings and abstract is incorporated herein by reference in its entirety.

### BACKGROUND OF THE INVENTION

The present invention relates to a method for cleaning a semiconductor device. More particularly, it relates to a method for cleaning a semiconductor device including shared contact holes formed therein.

In a contact hole formation step of a semiconductor device, in order to obtain a favorable contact resistance, it is necessary to remove an altered layer after dry etching for contact hole formation. The altered layer includes residual substances after dry etching (polymers containing products of residual gases and organic substances resulting from a resist) and an oxide layer of silicide at the bottom of each contact hole. In the related art, the altered layer is removed by cleaning with SPM (Sulfuric Acid/Hydrogen Peroxide/Water Mixture; a liquid mixture of sulfuric acid, aqueous hydrogen peroxide, and water) and APM (Ammonium Hydroxide/Hydrogen Peroxide/Water mixture; a liquid mixture of aqueous ammonia, aqueous hydrogen peroxide, and water).

More specifically, for example, a polymer containing products of CF (fluorocarbon) type residual gases and organic substances resulting from a resist is decomposed and removed by SPM. Further, for example, NiPtSiOx which is an oxide layer of silicide (NiPtSi; nickel platinum silicide) at the bottom of each contact hole is removed by etching with APM.

General technologies of cleaning of a substrate of a semiconductor device are described in, for example, Japanese Unexamined Patent Publication No. 2000-331978 (Patent Document 1), and Japanese Unexamined Patent Publication No. 2008-85124 (Patent Document 2). Japanese Unexamined Patent Publication No. 2000-331978 discloses as follows. In formation of a polymetal gate electrode, in order to remove resist residues, particles, polymers formed by dry etching, or the like, a SPM solution and an APM solution are successively used to clean a silicon substrate. Whereas, Japanese Unexamined Patent Publication No. 2008-85124 discloses as follows. After formation of a cobalt silicide layer on the semiconductor substrate surface at the bottom of each contact hole and the contact plug surface at the bottom of each contact hole, unreacted cobalt is removed using sulfuric acid or the like.

### [Patent Document 1]

### Japanese Unexamined Patent Publication No. 2000-331978

### [Patent Document 2]

### Japanese Unexamined Patent Publication No. 2008-85124

### SUMMARY OF THE INVENTION

For 32-nm node or later generation CMOS (Complementary Metal Oxide Semiconductor) devices, adoption of the high-k/metal gate structure has been studied. In the high-k/metal gate structure, a gate metal is used for a gate electrode layer. In the high-k/metal gate structure, in a SRAM (Static Random Access Memory) part, there can be adopted a shared contact including one contact hole reaching both of an active region and the gate electrode layer. For cleaning of the shared contact, the altered layer (residual substances after hole etching, the oxide layer of silicide) is required to be removed with the gate metal material (e.g., titanium nitride) and a silicide (e.g., NiPtSi) at the bottom of the shared contact hole simultaneously exposed from the shared contact hole.

The SPM cleaning solution for use in a conventional poly-Si (polycrystal silicon)/SiON (silicon oxynitride) gate structure dissolves the gate metal materials (e.g., titanium nitride). This deteriorates the transistor characteristics, which causes defects. For this reason, it is difficult to use the SPM cleaning solution for removal of the altered layer.

On the other hand, the fluorine-based cleaning solution does not dissolve the gate metal materials (e.g., titanium nitride). However, when the shared contact hole after dry etching is cleaned with a fluorine-based cleaning solution, there occurs a phenomenon that a silicide (e.g., NiPtSi) at the bottom of the shared contact hole damaged by dry etching is missing in blocks along the grain boundary. This causes a defect of an increase in contact resistance. For this reason, it is difficult to make compatible the removal of the altered layer and the acquisition of a favorable contact resistance.

The present invention was made in view of the foregoing problem. It is an object of the present invention to provide a method for cleaning a semiconductor device capable of making compatible the inhibition of dissolution of the gate metal materials and the acquisition of a favorable contact resistance.

A method for cleaning a semiconductor device in accordance with one embodiment of the present invention includes the following steps: a semiconductor substrate including silicon, and having a main surface is prepared; a multilayer gate including a metal layer and a silicon layer stacked sequentially from the bottom is formed over the main surface; a silicide is formed in each of the main surface and the silicon layer surface; an insulation layer is formed over the silicide in each of the main surface and the multilayer gate surface; a shared contact hole is formed in the insulation layer in such a manner that the silicide in each of the main surface of the semiconductor substrate and the surface of the multilayer gate is exposed from the insulation layer; and the shared contact hole is subjected to sulfuric acid cleaning, aqueous hydrogen peroxide cleaning, and APM cleaning in separate steps, respectively, and thereby an altered layer formed in the shared contact hole is removed.

In accordance with the method for cleaning a semiconductor device of this embodiment, sulfuric acid cleaning and aqueous hydrogen peroxide cleaning are respectively carried out in separate steps on a shared contact hole. For this reason, it is possible to more inhibit the dissolution of a metal layer than in the case of cleaning with SPM which is a mixed solution of sulfuric acid and aqueous hydrogen peroxide. The dissolution of the metal layer can be inhibited, so that the transistor characteristics are not deteriorated.

Whereas, even when sulfuric acid cleaning and aqueous hydrogen peroxide cleaning are respectively carried out in separate steps, the altered layer including a polymer can be removed. Further, APM cleaning is carried out, and hence the altered layer including a silicide oxide layer can also be removed.

Further, the dissolution of the metal layer can be inhibited. This eliminates the necessity of use of a fluorine-based cleaning solution. Therefore, silicide is not missing, which can provide a favorable contact resistance. From the description up to this point, it is possible to make compatible the inhibition of dissolution of the gate metal (metal layer) and the acquisition of a favorable contact resistance while removing the altered layer.

### BRIEF DESCRIPTION OF THE DRAWINGS

FIG. 1 is a schematic cross-sectional view showing a state in which source/drain regions are formed with a method for manufacturing a semiconductor device in Embodiment 1 of the present invention, and is a view showing the vicinity of a shared contact hole surrounded by an alternate long and short dash line of FIG. 11;

FIG. 2 is a schematic cross-sectional view showing the subsequent step of FIG. 1 in Embodiment 1 of the present invention;

FIG. 3 is a schematic cross-sectional view showing the subsequent step of FIG. 2 in Embodiment 1 of the present invention;

FIG. 4 is a schematic cross-sectional view showing the subsequent step of FIG. 3 in Embodiment 1 of the present invention;

FIG. 5 is a schematic cross-sectional view showing the subsequent step of FIG. 4 in Embodiment 1 of the present invention;

FIG. 6 is a schematic cross-sectional view showing the subsequent step of FIG. 5 in Embodiment 1 of the present invention;

FIG. 7 is an equivalent circuit view of a memory cell of a SRAM;

FIG. 8 is a schematic plan view showing a first layer from the bottom of a plan layout configuration of the semiconductor device in Embodiment 1 of this invention;

FIG. 9 is a schematic plan view showing a second layer from the bottom of a plan layout configuration of the semiconductor device in Embodiment 1 of this invention;

FIG. 10 is a schematic plan view showing a third layer from the bottom of a plan layout configuration of the semiconductor device in Embodiment 1 of this invention;

FIG. 11 is a schematic cross-sectional view along line V-V of FIGS. 8 to 10;

FIG. 12 is a view showing the respective etching rates with respect to a gate metal by sulfuric acid cleaning and aqueous hydrogen peroxide cleaning in Embodiment 1, and SPM cleaning of Comparative Example 1 of the present invention;

FIG. 13 is a view showing the temperature dependency of the etching rate with APM;

FIG. 14 is a schematic cross-sectional view showing a state in which an oxide layer is formed with a method for manufacturing a semiconductor device in Embodiment 2 of the present invention, and is a view showing the vicinity of a shared contact hole;

FIG. 15 is a schematic cross-sectional view showing the subsequent step of FIG. 14 in Embodiment 2 of the present invention;

FIG. 16 is a schematic cross-sectional view showing a state in which a third insulation layer is formed with a method for manufacturing a semiconductor device in Embodiment 3 of the present invention, and is a view showing the vicinity of a shared contact hole;

FIG. 17 is a schematic cross-sectional view showing the subsequent step of FIG. 16 in Embodiment 3 of the present invention;

FIG. 18 is a schematic cross-sectional view showing the subsequent step of FIG. 17 in Embodiment 4 of the present invention;

FIG. 19 is a schematic cross-sectional view showing a state in which a sacrifice layer is formed with a method for manufacturing a semiconductor device in Embodiments 5 to 7 of the present invention, and is a view showing the vicinity of a shared contact hole;

FIG. 20 is a schematic cross-sectional view showing the subsequent step of FIG. 19 in Embodiments 5 to 7 of the present invention;

FIG. 21 is a schematic cross-sectional view showing the subsequent step of FIG. 20 in Embodiments 5 to 7 of the present invention;

FIG. 22 is a schematic cross-sectional view showing the subsequent step of FIG. 21 in Embodiments 5 to 7 of this invention;

FIG. 23 is a schematic cross-sectional view showing the vicinity of a shared contact hole in Comparative Example 1; and

FIG. 24 is a schematic cross-sectional view showing the vicinity of a shared contact hole in Comparative Example 2.

### DETAILED DESCRIPTION OF THE PREFERRED EMBODIMENTS

Below, embodiments of the present invention will be described by reference to the accompanying drawings.

### Embodiment 1

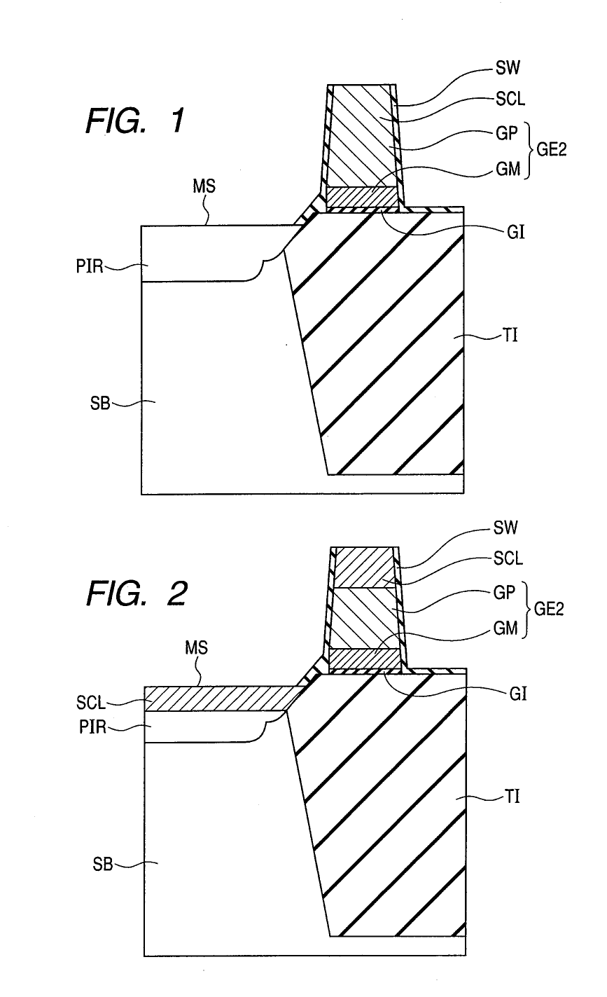

First, a manufacturing method including a cleaning method of a semiconductor device of this embodiment will be described by reference to FIGS. 1 to 6.

By reference to FIG. 1, into a semiconductor substrate SB including, for example, silicon, a filling material TI is embedded, thereby to form a trench isolation structure including STI (Shallow Trench Isolation). The filling material TI is formed of an isolation oxide film including, for example, a silicon oxide film. Over a main surface MS of the semiconductor substrate SB, a gate insulation layer GI and a conductive layer for gate electrode are formed. The gate insulation layer GI is formed of, for example, a High-k gate oxide film.

Over the conductive layer for gate electrode, for example, a photoresist (not shown) is applied. Subsequently, the photoresist is patterned. Using the pattern of the photoresist as a mask, the conductive layer for gate electrode is subjected to etching. As a result, the conductive layer for gate electrode is patterned, thereby to form a gate electrode layer GE2 which is a multilayer gate, and the like. The gate electrode layer GE2 is formed of gate metal GM which is a metal layer and gate polycrystal silicon (hereinafter, polycrystal silicon will be referred to as polysilicon) which is a silicon layer GP. The gate metal GM is formed of, for example, TiN (titanium nitride). Subsequently, the pattern of the photoresist is removed by ashing or the like.

Subsequently, using the gate electrode layer GE2 or the like as a mask, impurities are ion implanted. As a result of this and other processes, low concentration regions of source/drain regions are formed in the main surface MS of the semiconductor substrate SB.

Thereafter, an insulation layer for sidewall spacer is formed in such a manner as to cover the tops of the gate electrode layer GE2 and the like. The insulation layer is formed of, for example, a silicon oxide film. Over the insulation layer, for example, a SIN (silicon nitride) film is formed. Subsequently, etching back is performed on the entire surface until the main surface MS of the semiconductor substrate SB is exposed. At this step, the SiN film is removed, so that on the sidewalls of the gate electrode layer GE2 and the like, the insulation layer for sidewall spacer is left. As a result, a sidewall spacer SW is formed.

Using the sidewall spacer SW, the gate electrode layer GE2, and the like as a mask, impurities are ion implanted. As a result of this and other processes, high concentration regions of source/drain regions are formed in the main surface MS of the semiconductor substrate SB. In this manner, for example, p type source/drain regions PIR having a LDD (Lightly Doped Drain) structure are formed by the p type low concentration regions and high concentration regions.

By reference to FIG. 2, over the entire main surface MS of the semiconductor substrate SB, a refractory metal layer is formed, and is subjected to a heat treatment. This results in the formation of a silicide layer (silicide) SCL is formed over the gate electrode layer GE2 and the main surface MS of the semiconductor substrate SB. For example, the refractory metal layer is formed by successively depositing a NiPt (nickel platinum) film, and a TiN film. Subsequently, in a N₂ (nitrogen) atmosphere, first-stage annealing is performed, so that the reaction with silicon is allowed to proceed. Subsequently, unreacted excess portions of the NiPt film and the TiN film are removed by chemical liquid cleaning. Further, second-stage annealing is performed in a N₂ atmosphere, so that the reaction with silicon is allowed to proceed, resulting in the formation of a silicide layer SCL.

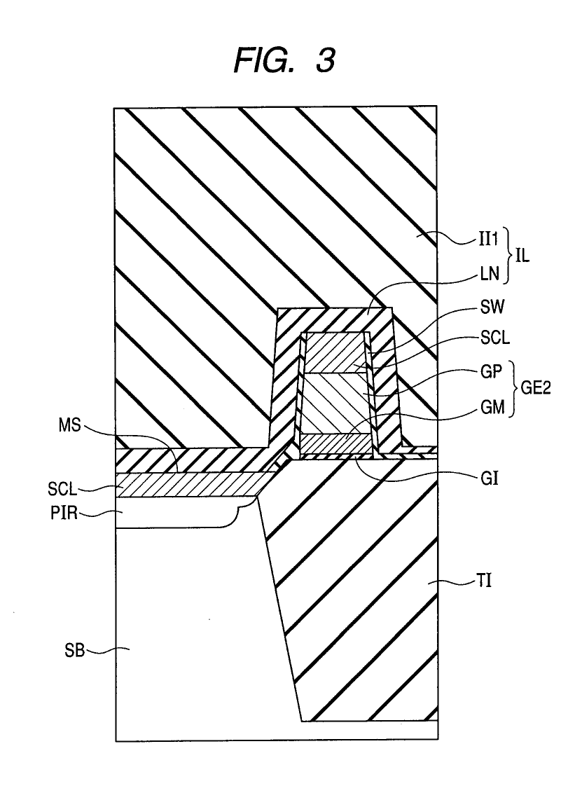

By reference to FIG. 3, a liner nitride film LN and an interlayer insulation layer II1 are successively stacked over the main surface MS of the semiconductor substrate SB in such a manner as to cover the gate electrode GE2, the sidewall spacer SW, and the like. The liner nitride film LN and the interlayer insulation layer II1 form an insulation layer IL. The insulation layer IL is formed over respective silicide layers SCL in the main surface MS of the semiconductor substrate SB and the surface of the gate electrode layer GE2. The liner nitride film LN is formed of, for example, a SiN film. The interlayer insulation layer II1 is formed of, for example, a silicon oxide film. Subsequently, the interlayer insulation layer II1 is subjected to CMP (Chemical Mechanical Polishing).

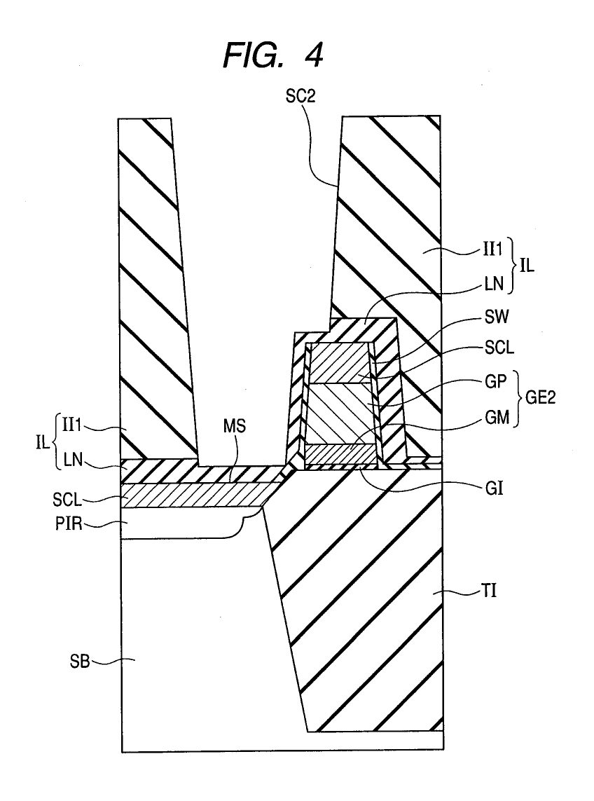

By reference to FIG. 4, a resist not shown is patterned on the interlayer insulation layer III. Using the pattern of the resist as a mask, the interlayer insulation layer II1 is subjected to etching. Subsequently, the resist is removed by ashing or the like. As a result, a hole for shared contact is formed above respective silicide layers SCL of the main surface MS of the semiconductor substrate SB which is an active region and the surface of the gate electrode layer GE2. Incidentally, there is also a pattern for forming a contact hole only in each of the main surface MS of the semiconductor substrate SB and the gate electrode layer.

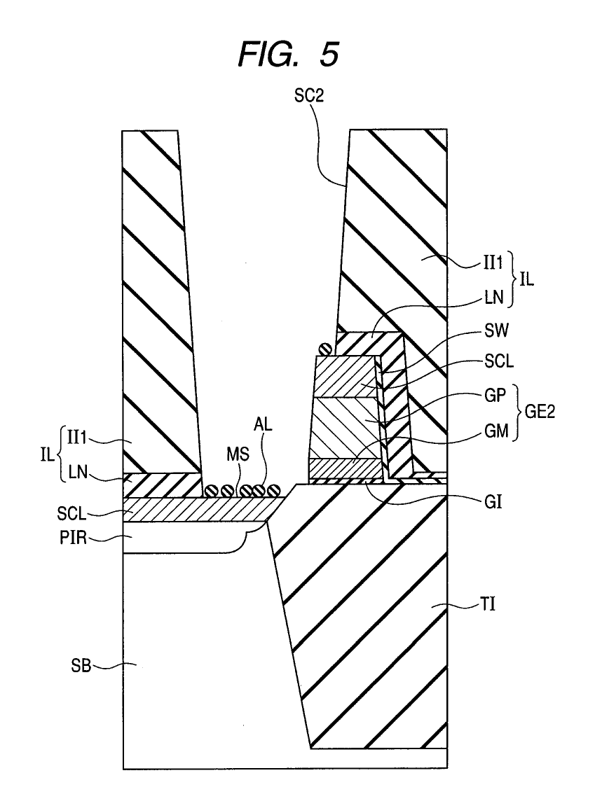

By reference to FIG. 5, the liner nitride film LN is etched without a mask, thereby to form a shared contact hole SC2 in such a manner that the silicide layer SCL is exposed from the insulation layer IL. At this step, portions of the liner nitride film LN and the sidewall spacer SW formed on the sidewall of the gate electrode layer GE2 in the shared contact hole SC2 are removed. Accordingly, at the sidewall of the gate electrode layer GE2 in the shared contact hole SC2, the gate polysilicon GP, the gate metal GM, and the like are exposed.

Whereas, over the silicide layers SCL in both of the main surface MS of the semiconductor substrate SB and the gate electrode layer GE2, an altered layer AL is formed. The altered layer AL is formed of, for example, a polymer containing a product of CF-based residual gases and organic substances resulting from the resist, and NiPtSiOx which is a silicide oxide layer. The altered layer AL inhibits a favorable contact with the conductive layer PL1, thereby to cause a defect of an increase in contact resistance. The conductive layer PL1 is, for example, a tungsten (W) plug.

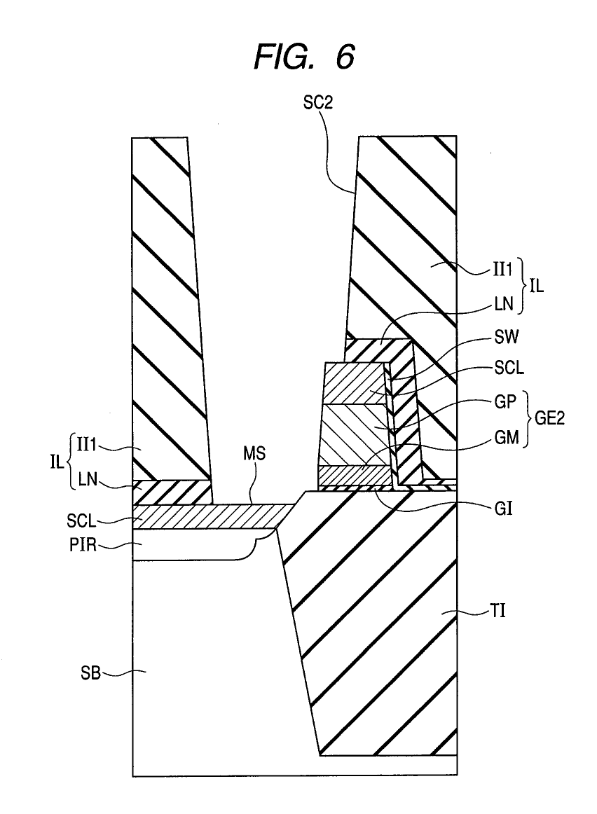

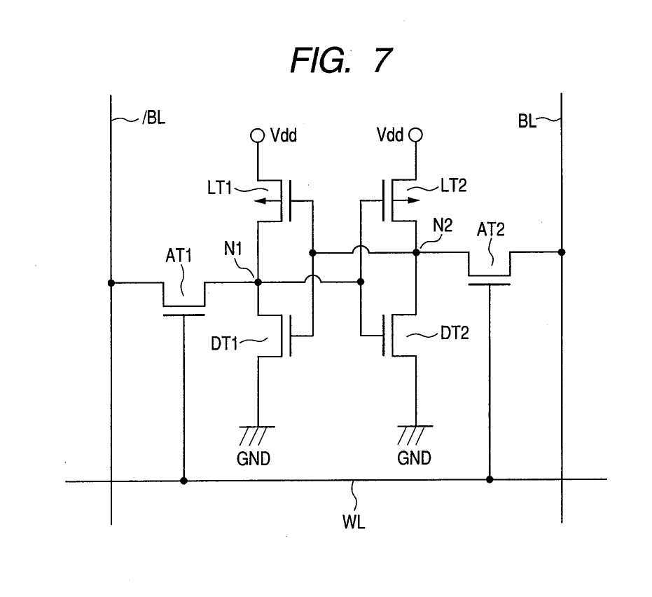

By reference to FIG. 6, the shared contact hole SC2 is subjected to sulfuric acid cleaning, aqueous hydrogen peroxide cleaning, and APM cleaning, respectively, in separate steps. As a result, the altered layer AL is removed. For sulfuric acid cleaning, the temperature of sulfuric acid is set at, for example, 80° C. The cleaning time is set at, for example, 1 minute. For aqueous hydrogen peroxide cleaning, the temperature of aqueous hydrogen peroxide is set at, for example, room temperature (25° C.). The cleaning time is set at, for example, 30 seconds.

For APM cleaning, the temperature (liquid temperature) of APM is set at, for example, 50° C. or less. The temperature of APM is preferably set at 50° C. to room temperature. As for the mixing ratio of APM, for example, 29 mass % aqueous ammonia, 30 mass % aqueous hydrogen peroxide, and pure water are set at a ratio of 1:1:50 or 4:1:200. The mixing ratio of 29 mass % aqueous ammonia and pure water is preferably 1:50 or more. The mixing ratio of 30 mass % aqueous hydrogen peroxide and pure water is preferably between 1:400 to 1:50.

The order of respective cleanings of sulfuric acid cleaning, aqueous hydrogen peroxide cleaning, and APM cleaning has no restriction. The polymer containing products of CF-based residual gases and organic substances resulting from the resist has water repellency. For this reason, in order to effectively carry out cleaning, cleanings are preferably carried out in the order of sulfuric acid cleaning, aqueous hydrogen peroxide cleaning, and APM cleaning.

Subsequently, in the shared contact, a conductive plug layer is formed. Then, as a device to which the shared contact is applied, a SRAM device will be described by reference to FIGS. 7 to 11.

By reference to FIG. 7, the SRAM is a volatile semiconductor storage device. The memory cell of the SRAM is, for example, a full CMOS (Complementary Metal Oxide Semiconductor) type memory cell.

In the SRAM, memory cells are disposed at the portions of intersection of complementary data lines (bit lines) BL and /BL and word lines WL disposed in a matrix. The memory cell includes a flip-flop circuit including a pair of inverter circuits and two access transistors AT1 and AT2. The flip-flop circuit forms two cross-coupled storage nodes N1 and N2, so that a bistable state of (High, Low) or (Low, High) is formed. The memory cell continues to hold a bistable state so long as it is applied with a prescribed power source voltage.

Each of a pair of the access transistors AT1 and AT2 includes, for example, an n channel MOS transistor (which will be hereinafter referred to as an nMOS transistor). One of the source/drain of the access transistor AT1 is electrically coupled with the storage node N1. The other of source/drain is electrically coupled with the bit line /BL. Whereas, one of source/drain of the access transistor AT2 is electrically coupled with the storage node N2. The other of source/drain is electrically coupled with the bit line BL. Further, respective gates of the access transistors AT1 and AT2 are electrically coupled with the word line WL. The word line WL controls the conduction and non-conduction states of the access transistors AT1 and AT2.

The inverter circuit includes one driver transistor DT1 (or DT2) and one load transistor LT1 (or LT2).

Each of a pair of the driver transistors DT1 and DT2 includes, for example, an nMOS transistor. The source of each of a pair of the driver transistors DT1 and DT2 is electrically coupled to GND (grounded potential). Whereas, the drain of the driver transistor DT1 is electrically coupled with the storage node N1, and the drain of the driver transistor DT2 is electrically coupled with the storage node N2. Further, the gate of the driver transistor DT1 is electrically coupled with the storage node N2, and the gate of the driver transistor DT2 is electrically coupled with the storage node N1.

Each of a pair of the load transistors LT1 and LT2 includes, for example, a p channel MOS transistor (which will be hereinafter referred to as a pMOS transistor). Each source of a pair of the load transistors LT1 and LT2 is electrically coupled with a Vdd power source voltage. Whereas, the drain of the load transistor LT1 is electrically coupled with the storage node N1, and the drain of the load transistor LT2 is electrically coupled with the storage node N2. Further, the gate of the load transistor LT1 is electrically coupled with the storage node N2, and the gate of the load transistor LT2 is electrically coupled with the storage node N1.

When data is written in the memory cell, the word line WL is selected. Thus, the access transistors AT1 and AT2 are brought into a conduction state, so that a voltage is forcedly applied to the bit line pair BL and /BL according to a desirable logic value. As a result, the flip-flop circuit is set to either of the bistable states. Further, when data is read from the memory cell, the access transistors AT1 and AT2 are brought into a conductive state, so that the electric potentials of the storage nodes N1 and N2 are transmitted to the bit lines BL and /BL, respectively.

In the configuration of the semiconductor device of this embodiment, the gate electrode layer of the load transistor LT1 and the drain region of the load transistor LT2 are electrically coupled with each other through the shared contact. The gate electrode layer of the load transistor LT2 and the drain region of the load transistor LT1 are electrically coupled with each other through the shared contact. Below, the configuration will be described.

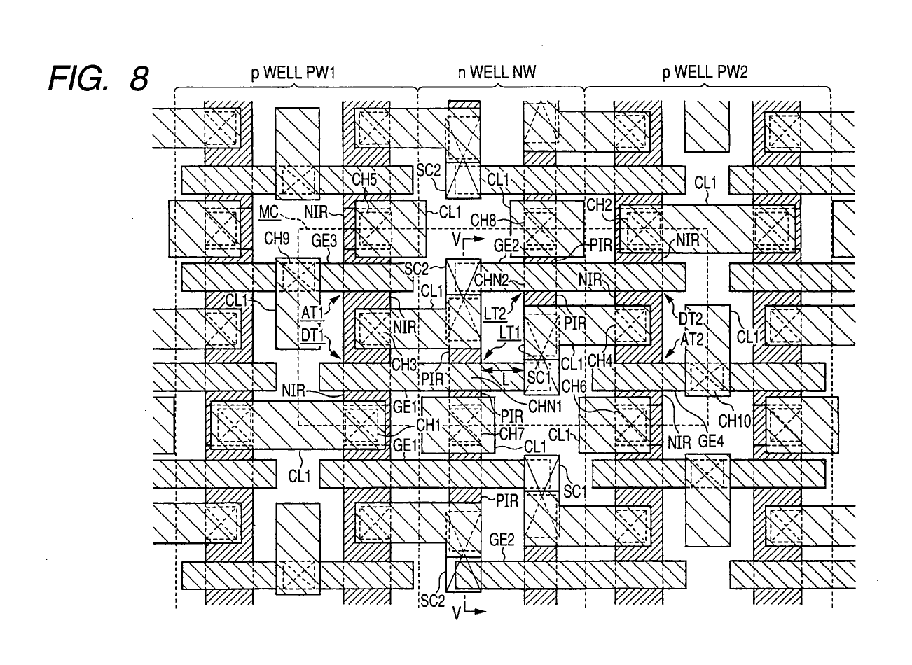

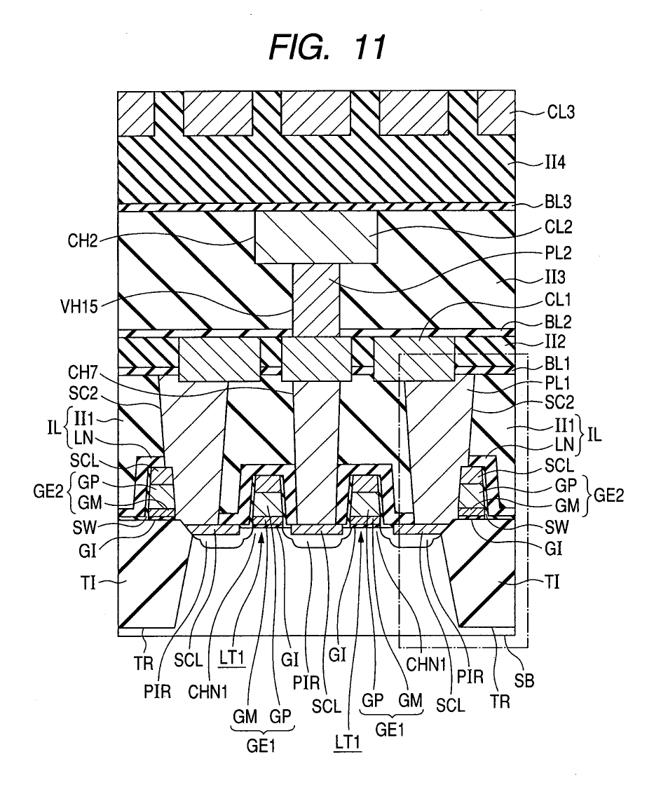

By reference to FIGS. 8 and 11, in the main surface of the semiconductor substrate SB, for example, a trench isolation structure including STI (Shallow Trench Isolation) is formed. The trench isolation structure has a trench isolation groove TR formed in the main surface of the semiconductor substrate SB, and a filling material TI filling the inside of the groove TR.

In the main surface of the semiconductor substrate SB isolated by the trench isolation structure, a plurality of SRAM memory cells are formed. In one SRAM memory cell region MC (the region surrounded by a broken line in FIG. 8), there are formed a pair of the driver transistors DT1 and DT2, a pair of the access transistors AT1 and AT2, and a pair of the load transistors LT1 and LT2.

A pair of the driver transistors DT1 and DT2 and a pair of the access transistors AT1 and AT2 respectively include, for example, nMOS transistors, and are formed in p type well regions PW1 and PW2 in the main surface of the semiconductor substrate SB. Whereas, a pair of the load transistors LT1 and LT2 respectively include, for example, pMOS transistors, and are formed in an n type well region NW in the main surface of the semiconductor substrate SB.

The driver transistor DT1 has a pair of n type impurity regions NIR serving as a pair of source/drain regions, and a gate electrode layer GE1. A pair of the n type impurity regions NIR are spaced from each other in a portion of the main surface of the semiconductor substrate SB in the p type well region PW1. The gate electrode layer GE1 is formed over a channel formation region interposed between a pair of the n type impurity regions NIR with a gate insulation layer (not shown) sandwiched therebetween.

The driver transistor DT2 has a pair of n type impurity regions NIR serving as a pair of source/drain regions, and a gate electrode layer GE2. A pair of the n type impurity regions NIR are spaced from each other in a portion of the main surface of the semiconductor substrate SB in the p type well region PW2. The gate electrode layer GE2 is formed over the channel formation region interposed between a pair of the n type impurity regions NIR with a gate insulation layer (not shown) sandwiched therebetween.

The access transistor AT1 has a pair of the n type impurity regions NIR serving as a pair of source/drain regions, and a gate electrode layer GE3. A pair of the n type impurity regions NIR are spaced from each other over a portion of the main surface of the semiconductor substrate SB in the p type well region PW1. The gate electrode layer GE3 is formed over the channel formation region interposed between a pair of the n type impurity regions NIR with a gate insulation layer (not shown) sandwiched therebetween.

The access transistor AT2 has a pair of the n type impurity regions NIR serving as a pair of source/drain regions, and a gate electrode layer GE4. A pair of the n type impurity regions NIR are spaced from each other in a portion of the main surface of the semiconductor substrate SB in the p type well region PW2. The gate electrode layer GE4 is formed over the channel formation region interposed between a pair of the n type impurity regions NIR with a gate insulation layer (not shown) sandwiched therebetween.

The load transistor LT1 has a pair of p type impurity regions PIR serving as a pair of source/drain regions, and the gate electrode layer GE1. A pair of the p type impurity regions PIR are spaced from each other in a portion of the main surface of the semiconductor substrate SB in the n type well region NW. The gate electrode layer GE1 is formed over the channel formation region interposed between a pair of the p type impurity regions PIR with a gate insulation layer GI sandwiched therebetween.

The load transistor LT2 has a pair of p type impurity regions PIR serving as a pair of source/drain regions, and the gate electrode layer GE2. A pair of the p type impurity regions PIR are spaced from each other in a portion of the main surface of the semiconductor substrate SB in the n type well region NW. The gate electrode layer GE2 is formed over the channel formation region CHN2 interposed between a pair of the p type impurity regions PIR with the gate insulation layer GI sandwiched therebetween

The drain region of the driver transistor DT1 and one of a pair of source/drain regions of the access transistor AT1 are formed of the same n type impurity region NIR. Whereas, the drain region of the driver transistor DT2 and one of a pair of the source/drain regions of the access transistor AT2 are formed of the mutually same n type impurity region NIR.

The gate electrode layer GE1 of the driver transistor DT1 and the gate electrode layer GE1 of the load transistor LT1 are formed of the mutually same conductive layer. Whereas, the gate electrode layer GE2 of the driver transistor DT2 and the gate electrode layer GE2 of the load transistor LT2 are formed of the mutually same conductive layer.

By reference to mainly FIG. 11, silicide layers SCL are formed in such a manner as to be in contact with respective gate electrode layers, and source/drain regions of the transistors DT1, DT2, AT1, AT2, LT1, and LT2. Further, a liner nitride film LN and an interlayer insulation layer II1 are successively stacked and formed over the semiconductor substrate SB in such a manner as to cover respective gate electrode layers, and source/drain regions of the transistors DT1, DT2, AT1, AT2, LT1, and LT2. In the liner nitride film LN and the interlayer insulation layer II1, a plurality of contact holes CH1 to CH8 and a plurality of shared contact holes SC1 and SC2 are formed.

By reference to mainly FIG. 8, specifically, in the liner nitride film LN and the interlayer insulation layer II1, there are formed the contact holes CH1 and CH2 reaching respective source regions of the driver transistors DT1 and DT2. Whereas, in the liner nitride film LN and the interlayer insulation layer II1, there are formed the contact holes CH3 and CH4 reaching one of a pair of source/drain regions of each of the access transistors AT1 and AT2 (each drain regions of the driver transistors DT1 and DT2). Whereas, in the liner nitride film LN and the interlayer insulation layer II1, there are formed the contact holes CH5 and CH6 reaching the other of a pair of source/drain regions of each of the access transistors AT1 and AT2. Whereas, in the liner nitride film LN and the interlayer insulation layer II1, there are formed the contact holes CH7 and CH8 reaching respective source regions of the load transistors LT1 and LT2.

Whereas, in the liner nitride film LN and the interlayer insulation layer II1, there is formed a shared contact hole SC1 reaching both of the gate electrode layer GE1 of the load transistor LT1 and the drain region of the load transistor LT2. Further, in the liner nitride film LN and the interlayer insulation layer II1, there is formed a shared contact hole SC2 reaching both of the gate electrode layer GE2 of the load transistor LT2 and the drain region of the load transistor LT1.

By reference to mainly FIG. 11, respective insides of a plurality of the contact holes CH1 to CH8 and the shared contacts hole SC1 and SC2 are filled with the conductive layer PL1 (FIG. 11). Over the interlayer insulation layer II1, the insulation layer BL1 and the interlayer insulation layer II2 are successively stacked and formed. In the insulation layer BL1 and the interlayer insulation layer II2, a plurality of through holes are formed. In respective insides of a plurality of the through holes, a plurality of conductive layers (first metal layers) CL1 are respectively embedded. A plurality of the conductive layers CL1 form a conductive layer pattern.

By reference to mainly FIG. 8, the conductive layers CL1 establish an electric coupling between the conductive layer PL1 in the shared contact hole SC1 and the conductive layer PL1 in the contact hole CH4. This establishes an electric coupling between the gate electrode layer GE1 of the load transistor LT1, the drain region of the load transistor LT2, the drain region of the driver transistor DT2, and one of a pair of source/drain regions of the access transistor AT2.

Whereas, the conductive layer CL1 establishes an electric coupling between the conductive layer PL1 in the shared contact hole SC2 and the conductive layer PL1 in the contact hole CH3. This establishes an electric coupling between the gate electrode layer GE2 of the load transistor LT2, the drain region of the load transistor LT1, the drain region of the driver transistor DT1, and one of a pair of source/drain regions of the access transistor AT1.

Whereas, the conductive layers PL1 in respective insides of the contact holes CH1, CH2, and CH5 to CH8 are also individually electrically coupled with the conductive layers CL1.

By reference to mainly FIG. 11, over the interlayer insulation layer II2, the insulation layer BL2 and the interlayer insulation layer II3 are successively stacked and formed. In the insulation layer BL2 and the interlayer insulation layer II3, a plurality of via holes VH11 to VH18 are formed. Grooves each for embedding conductive layer therein are formed in the surface of the interlayer insulation layer II3 in such a manner as to communicate with the respective plural via holes VH11 to VH18.

In each of a plurality of the via holes VH11 to VH18, the conductive layer PL2 is embedded. Further, in the respective plural grooves each for embedding the conductive layer, a plurality of conductive layers (second metal layers) CL2 are embedded, respectively. A plurality of the conductive layers CL2 form a conductive layer pattern.

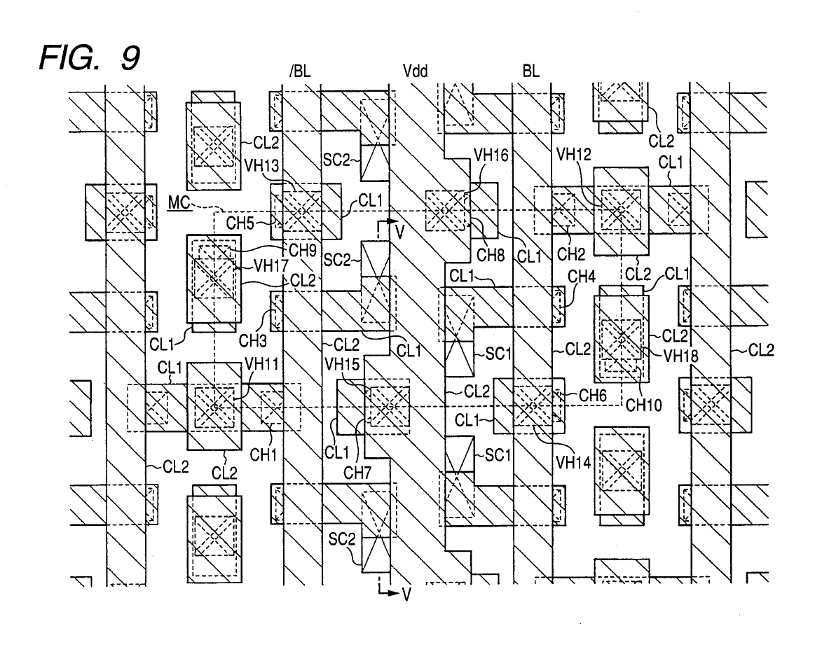

By reference to mainly FIG. 9, the conductive layer CL2 electrically coupled with the other of a pair of the source/drain regions of the access transistor AT1 through the via hole VH13 and the contact hole CH5 functions as a bit line /BL. Whereas, the conductive layer CL2 electrically coupled with the other of a pair of the source/drain regions of the access transistor AT2 through the via hole VH14 and the contact hole CH6 functions as a bit line BL. Whereas, the conductive layer CL2 electrically coupled with the source region of the load transistor LT1 through the via hole VH15 and the contact hole CH7, and electrically coupled with the source region of the load transistor LT2 through the via hole VH16 and the contact hole CH8 functions as a power source line Vdd. The bit lines BL and /BL, and the power source line Vdd extend in such a manner as to be parallel with each other along the longitudinal direction in the drawing.

Whereas, the conductive layers PL2 in respective insides of the via holes VH11, VH12, VH17, and VH18 also individually electrically coupled with the conductive layers CL2.

By reference to mainly FIG. 11, over the interlayer insulation layer II3, the insulation layer BL3 and the interlayer insulation layer II4 are successively stacked and formed. In the insulation layer BL3 and the interlayer insulation layer II4, a plurality of via holes VH21 to VH24 are formed. Grooves for embedding conductive layer therein are formed in the surface of the interlayer insulation layer II4 in such a manner as to communicate with a plurality of the via holes VH21 to VH24, respectively.

In the respective plural via holes VH21 to VH24, conductive layers (not shown) are embedded. Whereas, in the respective plural grooves each for embedding conductive layer therein, a plurality of conductive layers (third metal layers) CL3 are embedded, respectively. A plurality of the conductive layers CL3 form a conductive layer pattern.

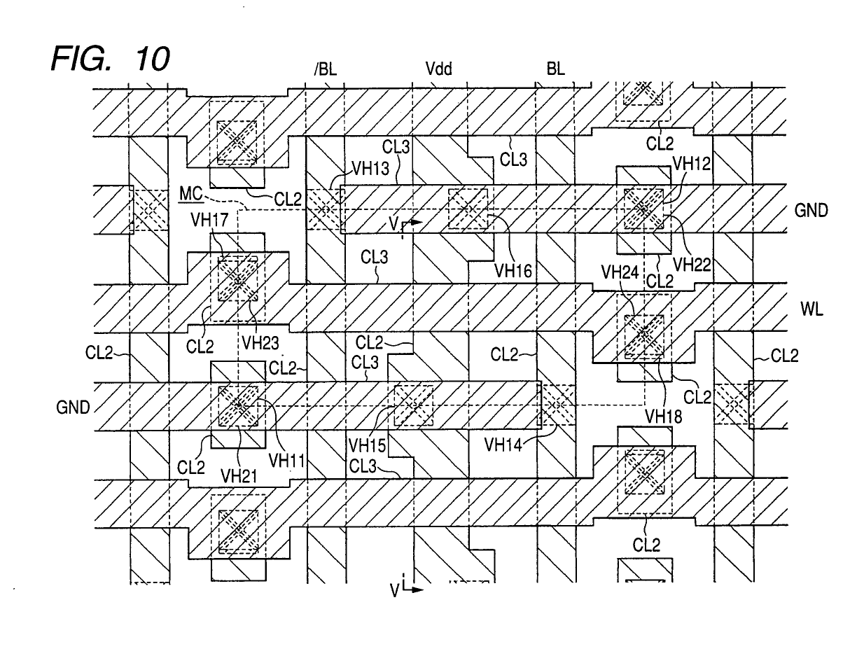

By reference to mainly FIG. 10, the conductive layer CL3 electrically coupled with the source region of the driver transistor DT1 through the via hole VH21, the via hole VH11, and the contact hole CH1 functions as a GND line. Whereas, the conductive layer CL3 electrically coupled with the source region of the driver transistor DT2 through the via hole VH22, the via hole VH12, and the contact hole CH2 functions as a GND line. Further, the conductive layer CL3 electrically coupled with the gate electrode layer GE3 of the access transistor AT1 through the via hole VH23, the via hole VH17, and the contact hole CH9, and electrically coupled with the gate electrode layer GE3 of the access transistor AT2 through the via hole VH24, the via hole VH18, and the contact hole CH10 functions as a word line WL. The GND lines and the word lines WL extend in such a manner as to be parallel with each other along the transverse direction in the drawing.

Then, the advantageous effects of this embodiment will be described by comparison with Comparative Examples. In accordance with this embodiment, the shared contact hole SC2 is subjected to sulfuric acid cleaning and aqueous hydrogen peroxide cleaning in separate steps, respectively. Accordingly, it is possible to more inhibit the dissolution of the gate metal GM (e.g., TiN) than in the case (Comparative Example 1) where cleaning is carried out with SPM which is a mixed solution of sulfuric acid and aqueous hydrogen peroxide. Below, this will be described.

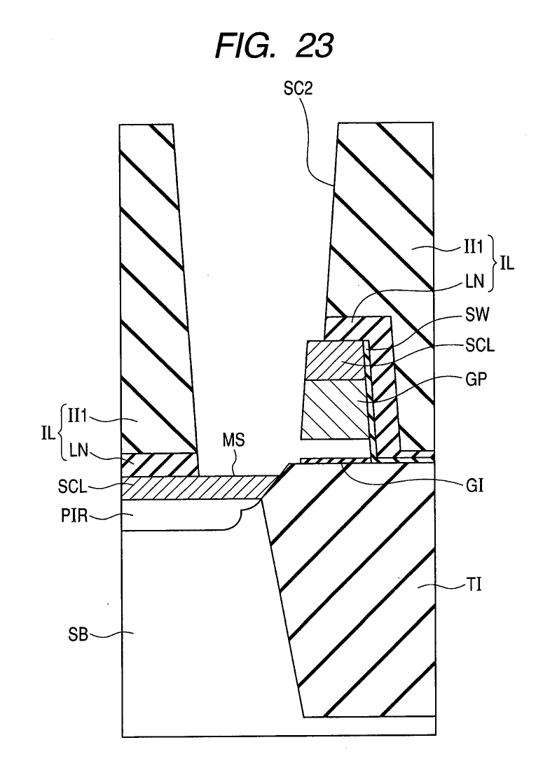

In Comparative Example 1, in order to remove the altered layer AL from the state of FIG. 5, the shared contact hole SC2 is continuously subjected to SPM cleaning and APM cleaning. Reference to FIG. 23 indicates as follows: in Comparative Example 1, the altered layer AL is removed by SPM cleaning and APM cleaning; however, the sidewall of the gate electrode layer is exposed, and hence the gate metal (e.g., TiN) is dissolved and eliminated.

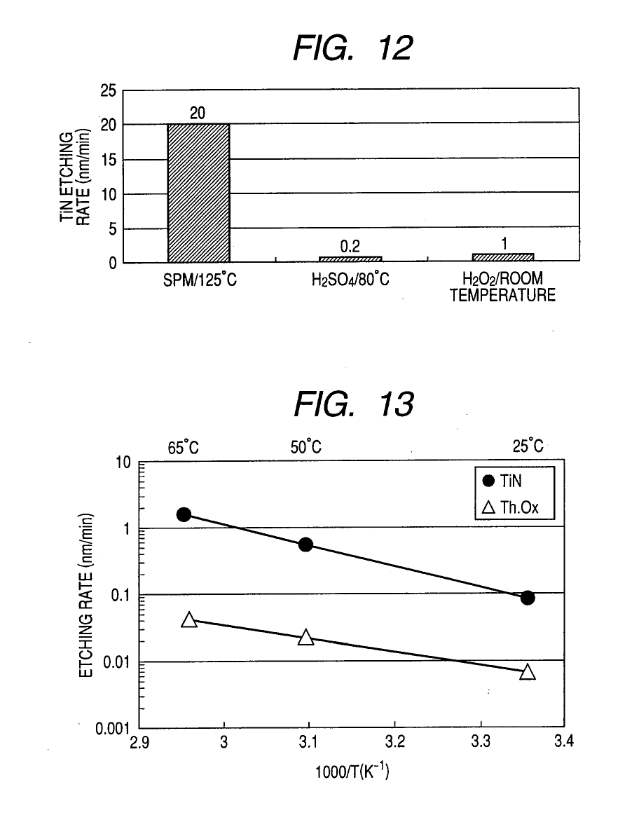

Thus, as a result of a close study thereon, by reference to FIG. 12, the etching rate with respect to TiN which is a material of the gate metal GM was found to be 20 nm/min for SPM. The present inventors further conducted a study in order to solve this problem. As a result, it has been found as follows: when etching operations with H₂SO₄ (sulfuric acid) and H₂O₂ (hydrogen peroxide) are carried out in separate steps, the etching rates with respect to TiN are 0.2 nm/min for H₂SO₄ (sulfuric acid) and 1 nm/min for H₂O₂ (hydrogen peroxide). Therefore, respective etching rates of sulfuric acid and aqueous hydrogen peroxide with respect to TiN result in much smaller values than the etching rate of SPM. This has indicated as follows: sulfuric acid cleaning and aqueous hydrogen peroxide cleaning are carried out in separate steps, respectively; as a result, it is possible to more inhibit dissolution of the gate metal GM (e.g., TiN) than SPM cleaning.

In this embodiment, the oxidation-reduction potential of sulfuric acid is lower than the oxidation-reduction potential of SPM. Therefore, the etching rate with respect to the gate metal GM (e.g., TiN) can be set lower than that in the case of cleaning with SPM. Therefore, it is possible to more inhibit removal of the gate metal GM than in the case of cleaning with SPM. The dissolution of the gate metal GM (e.g., TiN) can be inhibited, and hence the transistor characteristics are not deteriorated.

Whereas, even when sulfuric acid cleaning and aqueous hydrogen peroxide cleaning are carried out in separate steps, respectively, the altered layer including polymers can be removed. With SPM cleaning of Comparative Example 1, as shown with the following formula (1), Caro's acid (H₂SO₅) is formed from sulfuric acid (H₂SO₄) and hydrogen peroxide (H₂O₂).

[Chemical Formula 1]

H₂SO₄+H₂O₂→H₂SO₅+H₂O (1)

As shown with the following formula (2), Caro's acid oxidizes an organic substance R1 contained in the altered layer AL. In this manner, the polymer containing the organic substance R1 contained in the altered layer AL is decomposed and removed. Incidentally, a part of the organic substance R1 can remain as an organic substance R2 without being oxidized.

[Chemical Formula 2]

2H₂SO₅+R1→2H₂SO₄+CO₂+H₂O+R2 (2)

Incidentally, as shown with the following formula (3), Caro's acid oxidizes silicide (e.g., NiPtSi) contained in the altered layer AL. As a result, silicide (e.g., NiPtSi) is oxidized and protected.

[Chemical Formula 3]

NiPtSi+H₂SO₅→NiPtSiOx+H₂SO₄ (3)

In this embodiment, as shown with the following formulae (4) and (5), sulfuric acid oxidizes the organic substance R1 contained in the polymer of the altered layer AL. In this manner, the polymer containing the organic substance R1 contained in the altered layer AL is decomposed and removed. As a result, the polymer containing products of residual gases and organic substances resulting from the resist can be decomposed and removed. Incidentally, a part of the organic substance R1 can remain as the organic substance R2 without being oxidized.

[Chemical Formula 4]

H₂SO₄→SO₄²⁻+2H⁺ (4)

[Chemical Formula 5]

2SO₄²⁻+R1→2HSO₄⁻+CO₂+H₂O+R2 (5)

Incidentally, as shown in the following formula (6), hydrogen peroxide oxidizes silicide (e.g., NiPtSi) contained in the altered layer AL. As a result, silicide (e.g., NiPtSi) is oxidized and protected.

[Chemical Formula 6]

NiPtSi+H₂O₂→NiPtSiOx+H₂O (6)

In other words, in accordance with this embodiment, sulfuric acid cleaning and aqueous hydrogen peroxide cleaning are carried out in separate steps, respectively. As a result, it is possible to inhibit the dissolution of the gate metal GM without impairing the decomposition effect of the polymer containing products of residual gases and organic substances resulting from the resist.

Whereas, in accordance with this embodiment, by carrying out APM cleaning, it is possible to remove the oxide layer (e.g., NiPtSiOx) of silicide.

Further, in accordance with this embodiment, by reducing the temperature of APM cleaning, it is possible to improve the selectivity between the etching amount of the oxide layer (e.g., NiPtSiOx) of silicide (e.g., NiPtSi) at the bottom of the shared contact hole SC2 and the etching amount of the gate metal GM (e.g., TiN). This can make compatible the inhibition of dissolution of the gate metal GM and the acquisition of a favorable contact resistance. This point will be described in details.

By reference to FIG. 13, there is shown the temperature dependency of the etching rate with APM of the TiN which is the material of the gate metal GM and Th.Ox (thermal oxide film). In FIG. 13, for convenience of measurement, not the oxide layer of silicide (e.g., NiPtSiOx) but Th.Ox (thermal oxide film) is shown. However, regarding the temperature dependency of the etching rate, the silicide oxide layer (e.g., NiPtSiOx) and the Th.Ox have the same tendency. As shown in FIG. 13, a lower temperature results in better selectivity of Th.Ox with respect to TiN. Therefore, a lower temperature results in better selectivity of the silicide oxide layer (e.g., NiPtSiOx) with respect to TiN.

The etching amount necessary for removal of NiPtSiOx is about 1 nm in terms of Th.Ox. The etching amount of TiN is preferably controlled to 30 nm or less in consideration of the application to 32-nm node or later generation SoC (System on a Chip) products. When the etching amount of TiN is 30 nm or less, it is smaller than the distance to the active layer (arrow L in FIG. 8). Therefore, the transistor characteristics are not deteriorated.

By reference to FIG. 13, the etching rates when the temperature of APM is 50° C. are about 0.02 nm/min for Th. Ox, and about 0.6 nm/min for TiN. Therefore, when the temperature of APM is 50° C., the etching amount of NiPtSiOx is about 1 nm in terms of Th.Ox, and the etching amount of TiN is about 30 nm. As a result, by setting the treatment temperature of APM at 50° C. or less, it is possible to set the etching amount of TiN at 30 nm or less.

However, when the treatment temperature is too low, too much treatment time is taken in order to obtain the etching amount of NiPtSiOx of about 1 nm in terms of Th. Ox. This causes reduction of the productivity. Therefore, by setting the treatment temperature of APM at 50° C. or less, which is the treatment temperature not reducing the productivity, it is possible to improve the productivity while inhibiting the etching amount of TiN.

In this embodiment, removal of the gate metal GM can be inhibited. This eliminates the necessity of use of a fluorine-based cleaning solution. Therefore, silicide of the silicide layer SCL over the gate electrode layer GE2 and the silicide layer SCL over the main surface MS of the semiconductor substrate SB do not become missing in the shared contact hole SC2. Accordingly, it is possible to obtain a favorable contact resistance.

As a result, in this embodiment, it is possible to make compatible the inhibition of dissolution of the gate metal GM and the acquisition of a favorable contact resistance.

### Embodiment 2

This embodiment is mainly different from Embodiment 1 from the comparison therebetween in that an oxide film is formed on the sidewall of the gate electrode layer before performing of cleaning of the inside of the shared contact hole, and in that aqueous ammonia cleaning is performed in place of APM cleaning.

In this embodiment, up to the stage at which the shared contact hole SC2 is formed (see FIG. 5), the same manufacturing method as that in Embodiment 1 is applied.

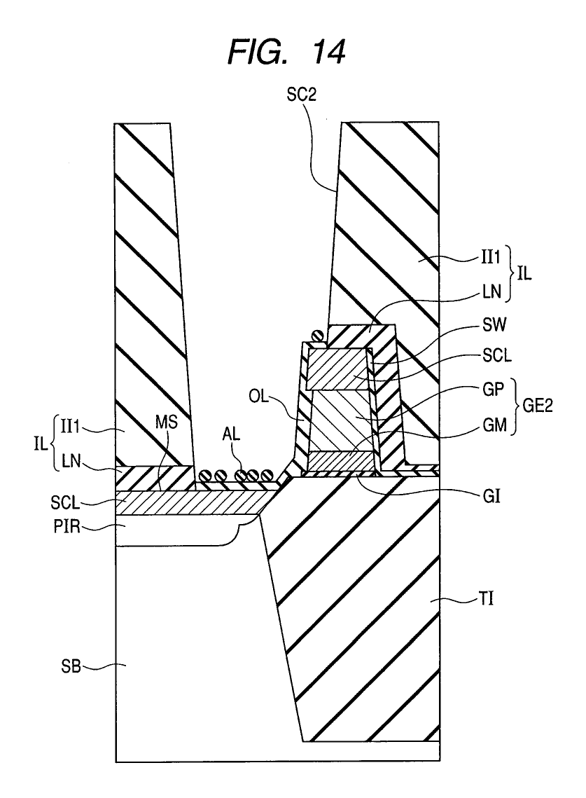

By reference to FIG. 14, in this embodiment, in the shared contact hole SC2, the sidewall of the gate electrode layer GE2, the silicide layer SCL over the gate electrode layer GE2, and the silicide layer SCL over the main surface MS of the semiconductor substrate SB are subjected to an ashing treatment, thereby to form a sacrifice layer OL therein. The sacrifice layer OL is formed of, for example, an oxide layer. Over the sacrifice layer OL, the altered layer AL is formed.

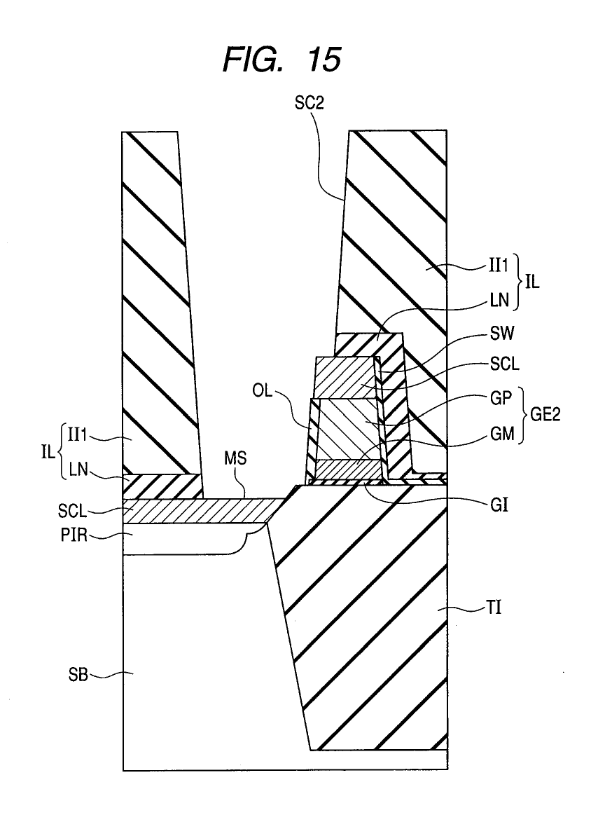

By reference to FIG. 15, the shared contact hole SC2 is subjected to sulfuric acid cleaning and aqueous hydrogen peroxide cleaning, separately. Aqueous ammonia cleaning is performed in place of APM cleaning of Embodiment 1.

Incidentally, other configurations and methods than these in this embodiment are the same as those in Embodiment 1. Therefore, the same elements are given the same reference numerals and signs, and a description thereon will not be repeated.

Then, the advantageous effects of this embodiment will be described by comparison with Comparative Examples. In accordance with this embodiment, sulfuric acid cleaning and aqueous hydrogen peroxide cleaning are performed in separate steps, respectively. As a result, it is possible to inhibit the dissolution of the gate metal GM without impairing the dissolution effect of the polymer containing products of residual gases and organic substances resulting from a resist.

In accordance with this embodiment, with aqueous ammonia cleaning, aqueous hydrogen peroxide is not contained. Therefore, it is possible to more inhibit the etching amount of the gate metal GM (e.g., TiN) as compared with APM cleaning. As a result, the deterioration of the transistor characteristics can be inhibited.

With APM cleaning of Comparative Example 1, as shown with the following formula (7), hydrogen peroxide (H₂O₂) oxidizes silicon (Si). As shown with the following formula (8), silicon oxide (SiO₂) reacts with hydroxide ions (OH⁻) of aqueous ammonia, thereby to be etched.

[Chemical Formula 7]

Si+2H₂O₂→SiO₂+2H₂O (7)

[Chemical Formula 8]

SiO₂+OH⁻→HSiO₃⁻ (8)

With aqueous ammonia cleaning of this embodiment, as shown with the following formula (9), silicon (Si) reacts with hydroxide ions (OH⁻) of aqueous ammonia, thereby to be etched.

[Chemical Formula 9]

Si+4OH⁻→Si(OH)₄ (9)

When silicon (Si) is directly etched by hydroxide ions (OH⁻) of aqueous ammonia, the etching rate is higher than that in the case where silicon undergoes oxidation with aqueous hydrogen peroxide. For this reason, with aqueous ammonia cleaning, silicon (Si) is more likely to be damaged than with APM cleaning.

In accordance with this embodiment, the sacrifice layer OL inhibits aqueous ammonia from coming in contact with the gate polysilicon GP. Therefore, it is possible to inhibit etching of the gate polysilicon GP with aqueous ammonia cleaning.

Further, the sacrifice layer OL prevents sulfuric acid and aqueous hydrogen peroxide from coming in contact with the gate metal GM. Therefore, it is possible to prevent the gate metal GM from being etched with sulfuric acid cleaning and aqueous hydrogen peroxide cleaning.

### Embodiment 3

This embodiment is mainly different from Embodiment 1 from comparison therebetween in that an insulation layer is formed at the sidewall part of the gate metal, in that SPM cleaning is carried out, and in that APM cleaning is carried out.

In this embodiment, up to the stage at which the interlayer insulation layer II1 is etched (see FIG. 4), the same manufacturing method as that in Embodiment 1 is applied. In this embodiment, the liner nitride film LN corresponds to the first insulation layer, and the interlayer insulation layer II1 corresponds to the second insulation layer. A hole for the shared contact hole SC2 is formed in such a manner that a portion of the liner nitride film LN immediately over the main surface MS of the semiconductor substrate SB and portions of the liner nitride film LN immediately over the top and over the sidewall of the gate electrode layer GE2 are exposed from the interlayer insulation layer II1.

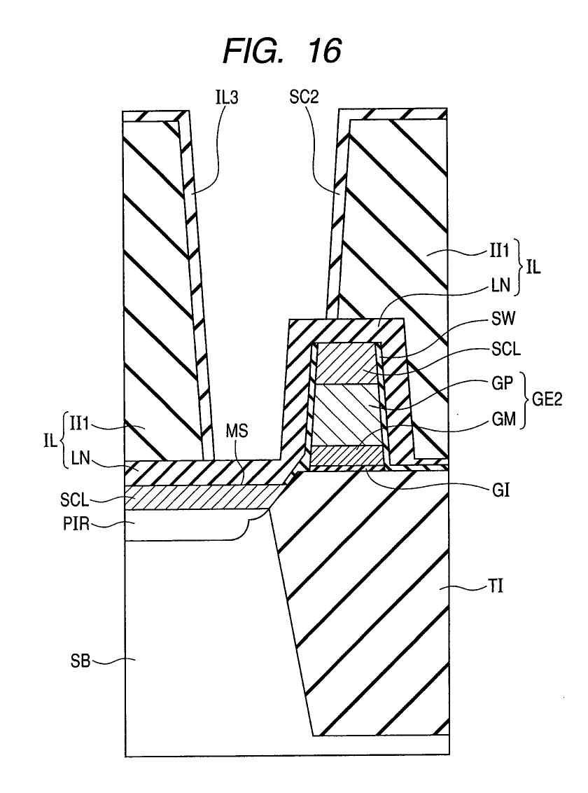

By reference to FIG. 16, a third insulation layer IL3 is formed by deposition over the hole for the shared contact hole SC2 and the interlayer insulation layer II1. The third insulation layer IL3 maybe formed at least over the sidewall part of the gate metal GM (e.g., TiN). The third insulation layer IL3 is formed of, for example, SiN. The third insulation layer IL3 may also be formed of, for example, a silicon oxide film. The third insulation layer IL3 is preferably formed with a thickness between a film thickness fully removable by a post-step etching and a film thickness such that the sidewall spacer SW remains after etching.

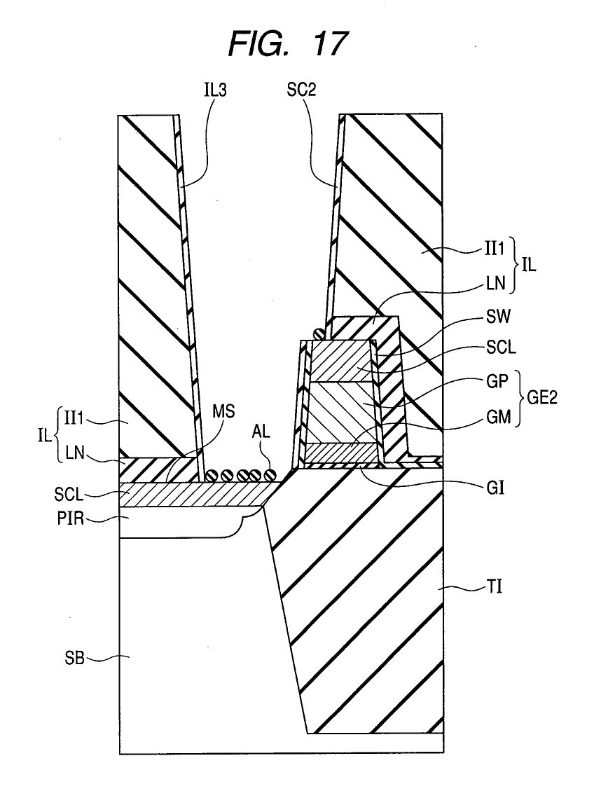

By reference to FIG. 17, the third insulation layer IL3 and the liner nitride film LN are etched without a mask, thereby to form the shared contact hole SC2. Portions of the third insulation layer IL3 and the liner nitride film LN at the bottom of the hole for the shared contact hole SC2 can be removed in such a manner as to prevent the gate polysilicon GP and the gate metal GM at the sidewall part of the gate electrode layer GE2 from being exposed due to anisotropy of dry etching. Over both silicide layers SCL in the main surface MS of the semiconductor substrate SB and the gate electrode layer GE2, the altered layer AL is formed.

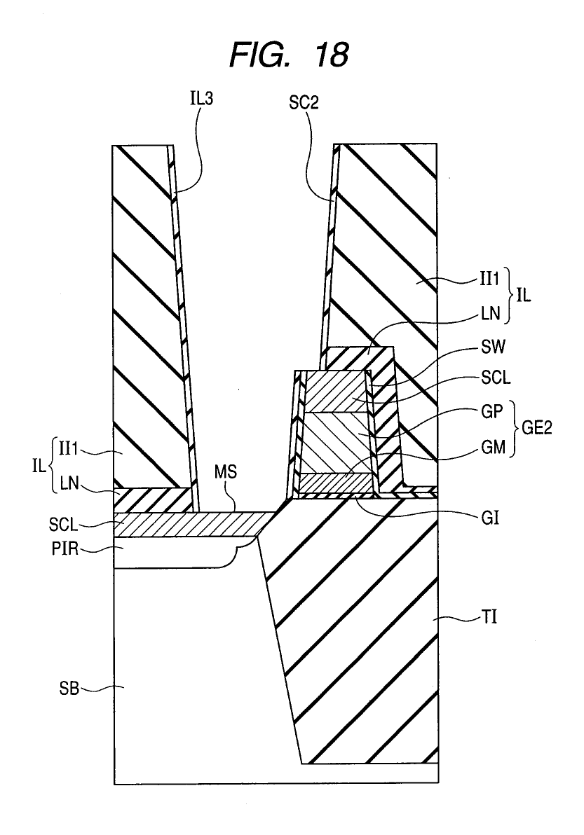

By reference to FIG. 18, the hole for the shared contact hole SC2 is subjected to SPM cleaning and APM cleaning, separately, with the sidewall part of the gate metal GM forming the sidewall of the gate electrode layer GE2 covered with the third insulation layer IL3.

Incidentally, other configurations and methods than these of this embodiment are the same as those of Embodiment 1. Therefore, the same elements are given the same reference numerals and signs, and a description thereon will not be repeated.

In accordance with this embodiment, the third insulation layer IL3 prevents the gate metal GM (e.g., TiN) from being exposed. For this reason, even when SPM cleaning and APM cleaning are performed, the dissolution of the gate metal GM can be prevented. This can prevent the deterioration of the transistor characteristics.

Further, with the manufacturing method of a semiconductor device, variations occur during formation of respective layers of the multilayered structure, and hence the overetching amount of each layer is set large. In this embodiment, the third insulation layer IL3 is formed later. For this reason, by controlling the overetching amount of the third insulation layer IL3, it is possible to set the overetching amount of each layer smaller as compared with the case where the third insulation layer IL3 is not formed.

### Embodiment 4

This embodiment is mainly different from Embodiment 1 from the comparison therebetween in that over the silicide layer SCL, a sacrifice layer is formed, and in that cleaning is carried out with a fluorine-based chemical liquid.

In this embodiment, up to the stage at which the silicide layer SCL is formed (see FIG. 2), the same manufacturing method as that of Embodiment 1 is applied.

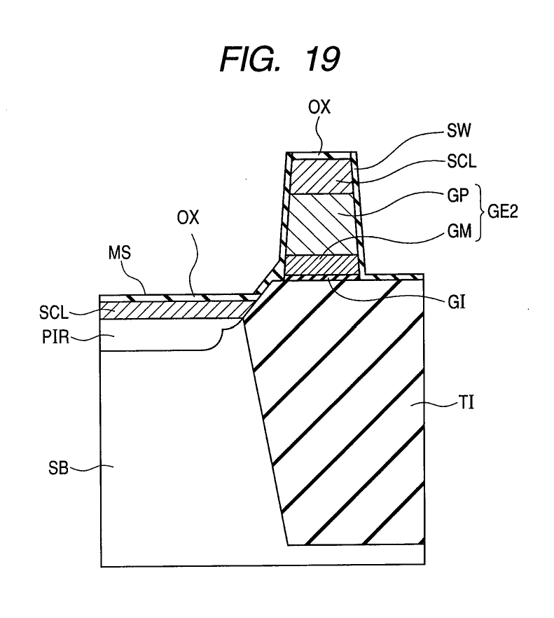

By reference to FIG. 19, over both the silicide layers SCL in the main surface MS of the semiconductor substrate SB and the gate electrode layer GE2, the sacrifice layer OX is formed. The sacrifice layer OX is formed, by being subjected to an oxidizing ashing treatment. As the oxidizing ashing treatment, for example, an about 2-minute treatment is performed with an O₂ (oxygen) plasma

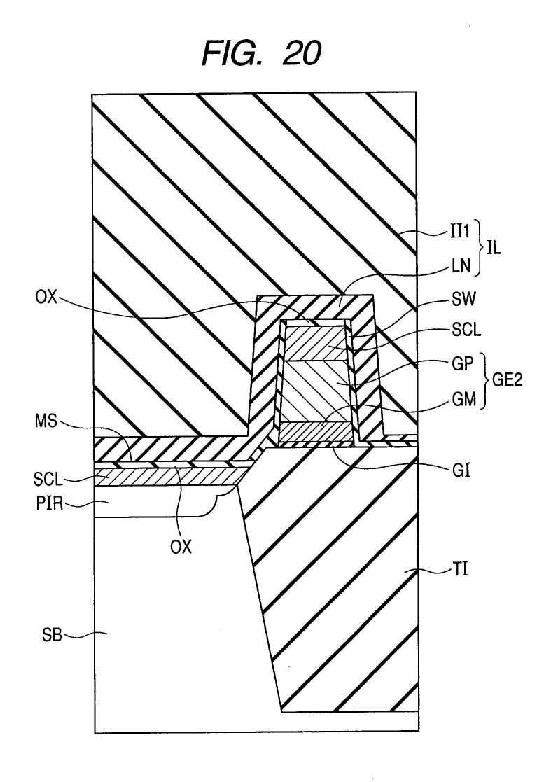

By reference to FIG. 20, the liner nitride film LN and the interlayer insulation layer II1 are successively stacked over the main surface MS of the semiconductor substrate SB in such a manner as to cover the sacrifice layer OX, the sidewall spacer SW, and the like.

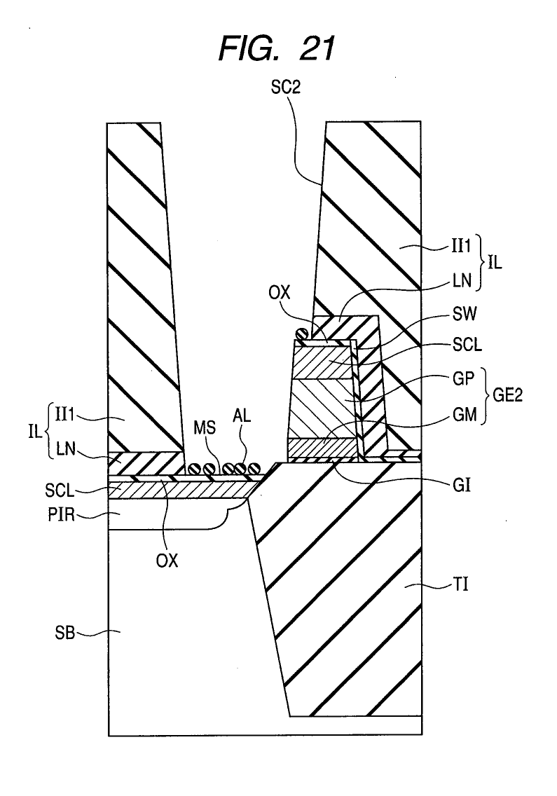

By reference to FIG. 21, the interlayer insulation layer II1 is etched. Etching of the liner nitride film LN results in the formation of the hole for the shared contact hole SC2. At this step, the liner nitride film LN and the sidewall spacer SW formed at the sidewall of the gate electrode layer GE2 in the hole for the shared contact hole SC2 are removed. Over both the sacrifice layers OX of the main surface MS of the semiconductor substrate SB and the gate electrode layer GE2, the altered layer AL is formed.

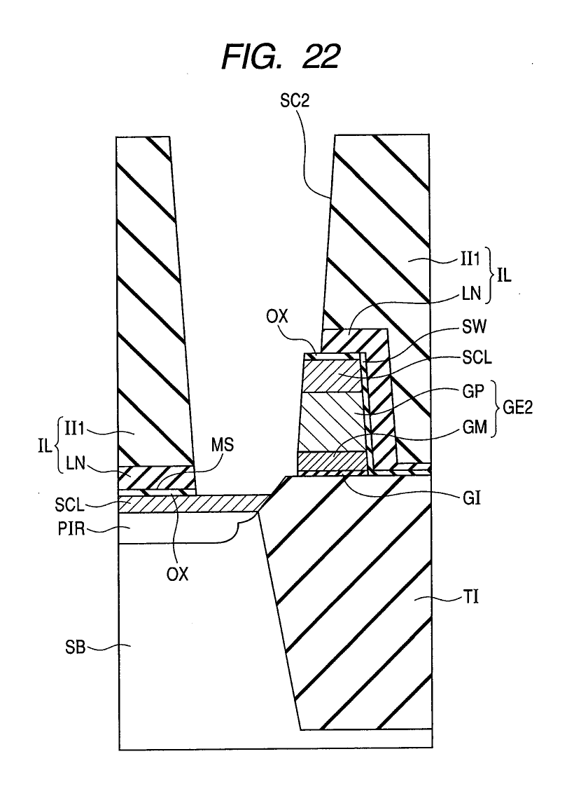

By reference to FIG. 22, the hole for the shared contact hole SC2 is subjected to cleaning with a fluorine-based chemical liquid. The fluorine-based chemical liquid includes, for example, a fluorine-based compound, an organic solvent, and water. As a result, the sacrifice layers OX immediately over the altered layer AL and the main surface MS of the semiconductor substrate SB, and immediately over the gate electrode layer GE2 are removed. Cleaning with a fluorine-based chemical liquid is preferably carried out for a time to just such a degree as to allow full removal of the sacrifice layers OX.

Incidentally, other configurations and methods than these in this embodiment are the same as those in Embodiment 1. Therefore, the same elements are given the same reference numerals and signs, and a description thereon will not be repeated.

Then, the advantageous effects of this embodiment will be described by comparison with Comparative Example.

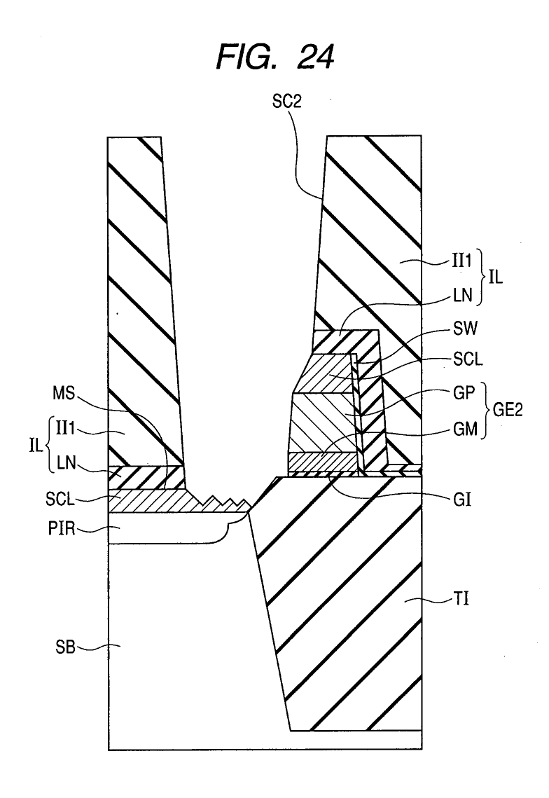

In Comparative Example 2, the shared contact hole SC2 is subjected to cleaning with a fluorine-based chemical liquid. By reference to FIG. 24, the altered layer AL is removed by cleaning with a fluorine-based chemical liquid. However, there occurs a phenomenon that the silicide (e.g., NiPtSi) damaged by dry etching becomes missing in blocks along the grain boundary. This causes a defect of an increase in contact resistance.

In accordance with this embodiment, by forming the sacrifice layers OX, it is possible to protect silicide from damages by dry etching. Further, it is possible to protect silicide from damages by the fluorine-based chemical liquid. As a result, a favorable contact resistance can be obtained.

In accordance with this embodiment, with cleaning with a fluorine-based chemical liquid, the dissolution of the gate metal GM (e.g., TiN) is inhibited. For this reason, the transistor characteristics are not deteriorated.

### Embodiment 5

This embodiment is mainly different from Embodiment 4 from the comparison therebetween in the formation method of the sacrifice layer.

By reference to FIG. 19, in this embodiment, the sacrifice layer OX is formed by being subjected to an oxidizing wet treatment. As the oxidizing wet treatment, for example, an about 10-minute treatment is carried out with a sulfuric acid hydrogen peroxide mixture aqueous solution obtained by mixing 98 mass % sulfuric acid and 30 mass % hydrogen peroxide in a volume ratio of 5:1. The temperature of the sulfuric acid hydrogen peroxide mixture aqueous solution is set at, for example, 130° C.

Incidentally, other configurations and methods than these in this embodiment are the same as those in Embodiment 4. Therefore, the same elements are given the same reference numerals and signs, and a description thereon will not be repeated.

This embodiment has the same advantageous effect as the advantageous effect of Embodiment 4.

### Embodiment 6

This embodiment is mainly different from Embodiment 4 from the comparison therebetween in the formation method of the sacrifice layer.

By reference to FIG. 19, in this embodiment, the sacrifice layer OX is formed by depositing a low temperature SiO₂ (silicon oxide film). The low temperature SiO₂ film is formed by, for example, depositing a 300° C. plasma TEOS (Tetraethoxysilane) film to about 1 to 2 nm.

Incidentally, other configurations and methods than these in this embodiment are the same as those in Embodiment 4. Therefore, the same elements are given the same reference numerals and signs, and a description thereon will not be repeated.

This embodiment has the same advantageous effect as the advantageous effect of Embodiment 4.

### Embodiment 7

This embodiment is mainly different from Embodiment 4 from the comparison therebetween in the formation method of the sacrifice layer.

By reference to FIG. 19, a refractory metal layer is formed over the entire main surface MS of the semiconductor substrate SB, and is subjected to a heat treatment. As a result, over the gate electrode layer GE2 and the main surface MS of the semiconductor substrate SB, the silicide layer SCL is formed. For example, the refractory metal layer is formed by successively depositing the NiPt film and the TiN film. Thereafter, a first-stage annealing is performed in a N₂ (nitrogen) atmosphere, so that the reaction with silicon proceeds. Then, unreacted excess portions of the NiPt film and the TiN film are removed by chemical liquid cleaning. Further, a second-stage annealing is performed in a N₂ atmosphere containing a trace amount of O₂ (oxygen), so that the reaction with silicon proceeds. This results in the formation of the silicide layer SCL and the silicide oxide layer. In this embodiment, the silicide oxide layer corresponds to the sacrifice layer OX. The flow rate of the O₂ gas is set at about 10% relative to the flow rate of the N₂ gas.

Incidentally, other configurations and methods than these in this embodiment are the same as those in Embodiment 4. Therefore, the same elements are given the same reference numerals and signs, and a description thereon will not be repeated.

This embodiment has the same advantageous effect as the advantageous effect of Embodiment 4.

Whereas, in accordance with this embodiment, it is not necessary to add a step of oxidizing silicide in order to form the sacrifice layer OX, which can improve the productivity.

In the foregoing description, silicide was described by taking NiPtSi as an example. However, it is essential only that silicide includes at least any of silicide of a metal and silicide of an alloy including one or more elements selected from a group comprised of Ni Co (cobalt), and Ti. For example, NiPtSi (nickel platinum silicide), NiSi (nickel silicide), CoSi (cobalt silicide), TiSi (titanium silicide), or the like is applicable.

In the foregoing description, the gate metal GM was described by taking TiN as an example. However, it is essential only that the multilayer gate contains at least any of a metal and an alloy including one or more elements selected from a group comprised of Ti, W, Ta (tantalum), and Al (aluminum), a nitride of the metal, a nitride of the alloy, a silicide of the metal, and silicide of the alloy. For example, TiN (titanium nitride), W (tungsten), WSi (tungsten silicide), TaSiN (tantalum nitride silicide), or TiAlN (titanium nitride aluminum) is applicable.

Incidentally, the alkali chemical liquid for use in APM cleaning is preferably adjusted to a pH of 7 or more.

Incidentally, the alkali chemical liquid for use in aqueous ammonia cleaning is preferably prepared with a pH of 7 or more.

Incidentally, the alkali chemical liquid may be a chemical liquid containing, other than ammonia, TMAH (tetramethyl ammonium hydroxide), amine, or the like.

It should be considered that the embodiments disclosed this time are illustrative and not limiting in all respects. The scope of the present invention is shown not byway of the foregoing description but by way of the appended claims, and is intended to include all the modifications within the meaning and the scope equivalent to those of the claims.

The present invention is in particular advantageously applicable to the cleaning method of a semiconductor device including shared contact holes formed therein.

1-2. (canceled)

3. A method for cleaning a semiconductor device, comprising the steps of:
preparing a semiconductor substrate comprising silicon, and having a main surface;
forming a multilayer gate including a metal layer and a silicon layer stacked sequentially from the bottom over the main surface;
forming a silicide in each of the main surface and the silicon layer surface;
forming an insulation layer over the silicide in each of the main surface and the multilayer gate surface;
forming a shared contact hole in the insulation layer in such a manner that the silicide in each of the main surface of the semiconductor substrate and the surface of the multilayer gate is exposed from the insulation layer;
forming a sacrifice layer at least over the side surface of the silicon layer of the multilayer gate exposed from the shared contact hole; and
subjecting the shared contact hole to sulfuric acid cleaning, aqueous hydrogen peroxide cleaning, and aqueous ammonium cleaning in separate steps, respectively, with the side surface of the silicon layer covered with the sacrifice layer, and thereby removing an altered layer formed in the shared contact hole.

4-9. (canceled)

10. The method for cleaning a semiconductor device according to claim 3, wherein the silicide comprises at least any of a silicide of a metal comprising Ni and a silicide of an alloy comprising Ni.

11. The method for cleaning a semiconductor device according to claim 3, wherein the multilayer gate comprises at least any of a metal comprising Ti and an alloy comprising Ti, a nitride of the metal, a nitride of the alloy, a silicide of the metal, and a silicide of the alloy.

12. (canceled)

13. The method for cleaning a semiconductor device according to claim 3, wherein the alkali chemical liquid for use in the aqueous ammonia cleaning is adjusted to a pH of 7 or more.
